(19) United States
(12) Patent Application Publication
(10) Pub. No.: US 2026/0309905 A1
(43) Pub. Date: Oct. 8, 2026

(54) POLARIZING PLATE AND OPTICAL DISPLAY APPARATUS

(71) Applicant: WUXI HENGXIN OPTOELECTRONIC MATERIALS CO., LTD., Wuxi (CN)

(72) Inventors: Ji Hwan PARK, Wuxi (CN); Bong Choon KIM, Wuxi (CN); Byungjoo BYUN, Wuxi (CN); Yoonjung KIM, Wuxi (CN); Daehee KWAK, Wuxi (CN); Hyeong Jun CHOI, Wuxi (CN); Yeeun PARK, Wuxi (CN)

(73) Assignee: WUXI HENGXIN OPTOELECTRONIC MATERIALS CO., LTD., Wuxi (CN)

(21) Appl. No.: 19/629,127

(22) Filed: Mar. 26, 2026

(30) Foreign Application Priority Data
Mar. 27, 2025 (KR) 10-2025-0039485

(51) Int. Cl. G02B 5/30

(52) U.S. Cl. CPC G02B 5/3083; G02B 5/3016; G02B 5/305

(57) ABSTRACT

Provided are a polarizing plate, including a polarizer; a polarizer protection layer sequentially laminated from the polarizer on one surface of the polarizer; and a laminate of a positive A layer and a positive C layer, wherein the polarizer protection layer is an anisotropic optical layer, wherein the polarizer protection layer has an in-plane phase difference (Re) of 10 nm or more and a degree of biaxiality (NZ) of more than 0.9 and 1.2 or less at a wavelength of 550 nm, and wherein a slow axis of the polarizer protection layer is parallel to a light absorption axis of the polarizer, and an optical display device including the same.

This application claims priority to Korean Patent Application No. 10-2025-0039485, titled “POLARIZING PLATE AND OPTICAL DISPLAY APPARATUS”, filed on Mar. 27, 2025, with the Korean Intellectual Property Office, which is incorporated herein by reference in its entirety.

### FIELD

The present invention relates to a polarizing plate and an optical display apparatus.

### BACKGROUND

Liquid crystal display devices and organic light-emitting diode display devices each include a polarizing plate. In particular, by including a polarizing plate, the organic light-emitting diode display device can effectively eliminate reflections caused by external light, thereby enabling the realization of clear image quality.

The polarizing plate includes a polarizer and a phase difference layer sequentially laminated on a lower surface of the polarizing plate. While a resin film may be used as the phase difference layer, in the case of a liquid crystal layer, it is formed by coating a composition for a liquid crystal layer, which can provide a thinning effect for the polarizing plate. The polarizing plate may further include a protective film between the polarizer and the phase difference layer. The protective film can increase the mechanical strength of the polarizing plate.

Generally, since the protective film must not affect the optical effects of the phase difference layer, an isotropic protective film is typically used. The isotropic protective film refers to a film in which the refractive index nx in the slow axis direction and the refractive index ny in the fast axis direction are identical at a wavelength of 550 nm. Therefore, the isotropic protective film is a non-stretched protective film, which allows the thickness of the polarizing to be increased.

The background art of the present invention is disclosed in Japanese Patent Laid-Open Publication No. 2006-251659 and the like.

### SUMMARY

An object of the present invention is to provide a polarizing plate that provides the optical effects, barrier effects and thinning effects of a phase difference layer.

Another object of the present invention is to provide a polarizing plate that provides the optical effects, barrier effect and thinning effects of a laminate of a positive A layer and a positive C layer.

An aspect of the present invention is a polarizing plate.

The polarizing plate includes a polarizer; a polarizer protection layer sequentially laminated from the polarizer on one surface of the polarizer; and a laminate of a positive A layer and a positive C layer, wherein the polarizer protection layer is an anisotropic optical layer, wherein the polarizer protection layer has an in-plane phase difference (Re) of 10 nm or more and a degree of biaxiality (NZ) of more than 0.9 and 1.2 or less at a wavelength of 550 nm, and wherein a slow axis of the polarizer protection layer is parallel to a light absorption axis of the polarizer.

Another aspect of the present invention is an optical display apparatus.

The optical display apparatus includes the polarizing plate of the present invention.

The polarizing plate of the present invention can provide a barrier effect while providing an optical effect of a laminate of a positive A layer and a positive C layer without adversely affecting the optical performance of a polarizing plate, even though the protection layer of a polarizer has anisotropy, thereby increasing the reliability of a polarizing plate and providing a thinning effect, and as a result, it can provide the thinning effect of an optical display apparatus.

### BRIEF DESCRIPTION OF THE DRAWINGS

FIG. 1 is a cross-sectional diagram of a polarizing plate according to one embodiment of the present invention.

FIG. 2 is a cross-sectional diagram of a polarizing plate according to another embodiment of the present invention.

### DETAILED DESCRIPTION OF EMBODIMENTS

The present invention is described in detail with reference to the attached drawings so that those skilled in the art can easily practice the same. The present invention may be embodied in various different forms and is not limited to the embodiments described herein.

The terms used herein are used merely to describe exemplary embodiments and are not intended to limit the present invention. Unless the context clearly indicates otherwise, the singular expression includes the plural expression.

In the drawings, parts that are unrelated to the description have been omitted to clearly describe the present invention, and identical or similar components throughout the specification are assigned with the same reference numerals. The lengths and sizes of each component in the drawings are for the purpose of describing the present invention, and the present invention is not limited to the lengths and sizes of each component described in the drawings.

In the present specification, “upper” and “lower” are defined based on the drawings, and depending on the viewing perspective, “upper” may be changed to “lower” and “lower” to “upper”. Furthermore, terms referred to as “above” or “on” may include not only the immediate upper part but also cases where other structures are interposed in between. On the other hand, terms referred to as “directly on”, “immediately above”, “directly formed” or “directly in contact formed” mean that no other structure is interposed in between.

In the present specification, “an in-plane phase difference (Re)”, “a thickness direction phase difference (Rth)” and “a degree of biaxiality (NZ)” are expressed by Equations A, B and C below:

$$R e = ( nx - ny ) ⨯ d \qquad [ Equation A ]$$

$$Rth = ( ( nx + ny ) / 2 - nz ) ⨯ d \qquad [ Equation B ]$$

$$NZ = ( nx - nz ) / ( nx - ny ) \qquad [ Equation C ]$$

(In Equations A, B and C above, nx, ny and nz are a refractive index in the slow axis direction, a refractive index in the fast axis direction and a refractive index in the thickness direction of the corresponding optical element, respectively, at the measurement wavelength, and d is a thickness of the corresponding optical element (unit: nm).)

Unless otherwise specifically mentioned in the present specification, the in-plane phase difference, the thickness direction phase difference and the degree of biaxiality are values measured by transmitting light in the normal direction to the in-plane direction of the optical element.

When describing angles in the present specification, “+” indicates an angle in the clockwise direction relative to a reference (0°), and “−” indicates an angle in the counterclockwise direction relative to a reference (0°).

In the present specification, “(meth)acrylic” may mean acrylic or methacrylic.

When describing numerical ranges in the present specification, “X to Y” means X or more and Y or less.

The polarizing plate of the present invention may be applied to a light-emitting diode display device including a liquid crystal display device or an organic light-emitting diode display device. For example, the polarizing plate may be used as an anti-reflection polarizing plate in an organic light-emitting diode display device.

The polarizing plate of the present invention includes a laminate of a positive A layer and a positive C layer as a protection layer on one surface of a panel of a polarizer. Accordingly, the polarizing plate may provide an optical effect, namely an anti-reflection effect, derived from the laminate. Here, the “anti-reflection effect” may refer to an effect that lowers the maximum reflectance in all directions and reduces a color change between the front surface and the side surface.

The polarizing plate further includes a polarizer protection layer described below between a polarizer and the laminate. The polarizer protection layer is an anisotropic optical layer, the polarizer protection layer has an in-plane phase difference (Re) of 10 nm or more and a degree of biaxiality (NZ) of more than 0.9 and 1.2 or less at a wavelength of 550 nm, and a slow axis of the polarizer protection layer is parallel to a light absorption axis of the polarizer.

In one embodiment, a light absorption axis of the polarizer may be a machine direction of the polarizer.

In one embodiment, the anisotropic optical layer may be manufactured by stretching as described below. Accordingly, the anisotropic optical layer may provide a thinning effect of the polarizing plate compared to a polarizer protection layer manufactured without stretching, for example, an isotropic optical layer.

The anisotropic optical layer has the n-plane phase difference and the degree of biaxiality and satisfies the axial relationship, thereby not affecting the realization of the optical effects, that is, the anti-reflection effect, derived from the laminate of the positive A layer and the positive C layer.

In one embodiment, the anisotropic optical layer may be a polyester-based, polymethyl methacrylate-based or cyclic olefin polymer-based protection layer. Accordingly, the polarizing plate may also provide a barrier effect by blocking the contamination of a dichroic material of the laminate and the contamination of a dichroic material of a panel of the optical display apparatus when a dichroic material, such as iodine, is leached from the polarizer after the polarizing plate is left at high temperature and high humidity for a long period of time.

According to one embodiment, the polarizing plate includes a polarizer; a polarizer protection layer sequentially laminated from the polarizer on one surface of the polarizer; and a laminate of a positive A layer and a positive C layer, wherein the polarizer protection layer is an anisotropic optical layer, wherein the polarizer protection layer has an in-plane phase difference (Re) of 10 nm or more and a degree of biaxiality (NZ) of more than 0.9 and 1.2 or less at a wavelength of 550 nm, and wherein a slow axis of the polarizer protection layer is parallel to a light absorption axis of the polarizer.

Hereinafter, the polarizing plate according to one embodiment will be described in detail.

### Polarizer

A polarizer includes a light-absorbing polarizer having the functions of separating incident light into two orthogonal polarization components, transmitting one polarization component and absorbing the other.

In one embodiment, among the in-plane directions of the polarizer, the axis with a higher refractive index may be a light absorption axis of the polarizer (e.g., a mechanical direction (MD) of the polarizer), and the axis with a lower refractive index may be a light transmission axis of the polarizer (e.g., a transverse direction (TD) of the polarizer).

The polarization degree of the polarizer may be 95% or more, specifically 95% to 100%, and more specifically 98% to 100%. Within the above range, excellent optical properties of the polarizer may be implemented.

The polarizer may include a uniaxially stretched polarizer containing a dichroic dye. Specifically, a polarizer containing a dichroic dye may include a polarizer manufactured by stretching a substrate film for the polarizer uniaxially by MD and dyeing the same with a dichroic dye (e.g., iodine or potassium iodide as an iodine-containing material). The substrate film for the polarizer may include a polyvinyl alcohol-based film or a derivative thereof, but is not limited thereto. The polarizer may be manufactured according to conventional methods known to those skilled in the art.

The polarizer may have a thickness of 1 μm to 40 μm, for example, 5 μm to 30 μm, or 5 μm to 15 μm. Within the above range, it may be used in a polarizer plate.

### Polarizer Protection Layer

A polarizer protection layer is located on a panel side adjacent to the polarizer relative to the laminate of a positive A layer and a positive C layer described below.

The polarizer protection layer is an anisotropic optical layer. Here, the “anisotropic optical layer” refers to an optical layer in which the refractive index nx in the slow axis direction and the refractive index ny in the fast axis direction at a wavelength of 550 nm are not equal.

In one embodiment, the anisotropic optical layer may be a polymer film manufactured by stretching. The polymer film may be advantageous in providing a thinning effect compared to a non-stretched polarizer protection layer, for example, an isotropic optical layer. In addition, the polymer film may be advantageous in providing a barrier effect compared to a polarizer protection layer in the form of a liquid crystal layer.

Here, the “barrier effect” means that when a polarizing plate is left in high temperature and high humidity for a long period of time, the panel may be prevented from corroding by a dichroic substance, such as iodine, when the dichroic substance leaches from the polarizer.

For example, the polymer film may be a polyester-based, polymethyl methacrylate-based or cyclic olefin polymer-based film. The polyester-based film or the cyclic olefin polymer-based film may be suitable for providing the barrier effect. The polyester-based film may be a polyethylene terephthalate, polyethylene naphthalate, polybutylene terephthalate or polybutylene naphthalate film.

The anisotropic optical layer has (i) an in-plane phase difference (Re) of 10 nm or more at a wavelength of 550 nm, and (ii) a degree of biaxiality (NZ) of more than 0.9 and 1.2 or less at a wavelength of 550 nm, and (iii) a slow axis of the anisotropic optical layer is parallel to a light absorption axis of the polarizer.

By satisfying all of (i) to (iii) above, the anisotropic optical layer may not affect the optical effect caused by the laminate of a positive A layer and a positive C layer, that is, the anti-reflection effect.

While color distortion due to phase difference typically occurs when only (i) among (i) to (iii) is satisfied, the inventors of the present invention have discovered through research that color distortion does not occur when all conditions of (i) to (iii) are satisfied in the present invention.

In one embodiment, the anisotropic optical layer may have an in-plane phase difference of 10 to 1,000 nm, for example, 100 to 1,000 nm, at a wavelength of 550 nm.

If (ii) among (i) to (iii) above is not satisfied, there may be a problem in that the effects of the polarizing plate described above may not be implemented. If the degree of biaxiality (NZ) is 0.9 or less, the color change between the front surface and the side surface may increase. If the degree of biaxiality (NZ) is more than 1.2, the maximum reflectance may increase.

In one embodiment, the anisotropic optical layer may have a degree of biaxiality of 1 to 1.2 at a wavelength of 550 nm.

If (iii) among (i) to (iii) above is not satisfied, there may be a problem in that the maximum reflectance increases, and the color change between the front surface and the side surface increases.

The polarizer protection layer may be manufactured by producing a non-stretched film from a composition including a resin by melt extrusion or solution casting, and by uniaxial stretching of the non-stretched film in the machine direction. For example, the stretching ratio may be 1.5 times or more, for example, 2 to 6 times.

In one embodiment, the resin may include one or more of a polyester-based resin, a polymethyl methacrylate-based resin or a cyclic olefin polymer-based resin. In this case, the anisotropic optical layer may be advantageous for providing a barrier effect.

In one embodiment, a slow axis of the polarizer protection layer may be parallel to a mechanical direction of the polarizer protection layer.

The thickness of the polarizer protection layer may be 20 μm or less, for example, 10 μm or less, for example, more than 0 μm and 10 μm or less. Within the above range, a thinning effect of the polarizer plate may be provided.

The polarizing plate may include an adhesive layer or a bonding layer between the anisotropic optical layer and the positive A layer. The polarizing plate may include an adhesive layer or a bonding layer between the positive A layer and the positive C layer.

### Phase Difference Layer Laminate

The laminate of a positive A layer and a positive C layer is laminated in the order of a polarizer, a polarizer protection layer and a phase difference layer laminate.

In one embodiment, in the case of an anti-reflection polarizing plate applied to an organic light-emitting display, a polarizer, a polarizer protection layer, a positive A layer and a positive C layer may be laminated in this order. In this case, the order of the positive A layer and the positive C layer may be reversed.

The positive C layer may satisfy the refractive index relationship of nz>nx≈ny. The thickness direction phase difference of the positive C layer at a wavelength of 550 nm may be −150 nm to −50 nm, for example, −110 nm to −50 nm or −90 nm to −50 nm. Within the above range, it may be easy to provide an anti-reflection effect.

The in-plane phase difference of the positive C layer at a wavelength of 550 nm may be 0 nm to 10 nm, and preferably 0 nm to 5 nm. Within the above range, it may be easy to provide the above-described thickness direction phase difference.

The positive A layer can satisfy the refractive index relationship of nx>ny≈nz. The in-plane phase difference of the positive A layer at a wavelength of 550 nm may be 100 nm to 160 nm, and preferably 110 nm to 150 nm. Within the above range, it may be easy to provide an anti-reflection effect.

The degree of biaxiality of the positive A layer at a wavelength of 550 nm may be 0.9 to 1.2, and preferably 0.95 to 1.1. Within the above range, it may be helpful to provide an anti-reflection effect.

The positive C layer may be a liquid crystal layer or a non-liquid crystal layer.

When the positive C layer is a liquid crystal layer, the positive C layer may be formed by coating a composition for a liquid crystal layer onto a substrate film and the like, and then drying and curing the same. Since the positive C layer in the form of a liquid crystal layer is manufactured without processes such as stretching, it may be easy to reduce the bending of the polarizing plate. The composition for a liquid crystal layer may be formed from a conventional composition for a liquid crystal layer known to those skilled in the art. For example, the composition for a liquid crystal layer may be a nematic or discotic liquid crystal.

If the positive C layer is a non-liquid crystal layer, the positive C layer may be formed by coating a composition for a non-liquid crystal layer onto a substrate film and the like, and then drying and curing the same. Since the positive C layer in the form of a non-liquid crystal layer is a non-stretched coating layer and is manufactured without processes such as stretching, it may be easy to reduce the bending of the polarizing plate.

The composition forming the positive C layer as a non-stretched coating layer may include compounds such as resins, oligomers, or monomers, such as cellulose-based or polystyrene-based resins, cellulose-based or polystyrene-based resins.

The cellulose-based compound may include at least a unit in which at least some of hydroxyl groups [C2 hydroxyl groups, C3 hydroxyl groups or C6 hydroxyl groups] of sugar monomers constituting cellulose are substituted with acyl groups or ether groups. That is, the cellulose-based compound may include one or more of cellulose ester-based polymers and cellulose ether-based polymers.

For example, the cellulose-based polymer may include a cellulose ester-based polymer including at least a unit in which at least some of hydroxyl groups [C2 hydroxyl groups, C3 hydroxyl groups or C6 hydroxyl groups] of sugar monomers constituting cellulose are substituted with acyl groups, as shown in Chemical Formula 1 below: In this case, the acyl groups may be substituted or unsubstituted.

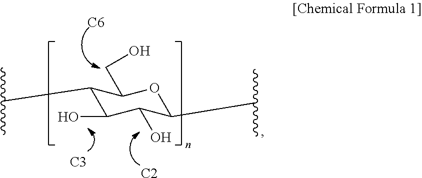

(In Chemical Formula 1 above, n is an integer of 1 or more)

Substituents for the cellulose ester-based group or acyl group may each include one or more of halogen, nitro, alkyl (e.g., alkyl group having 1 to 20 carbon atoms), alkenyl (e.g., alkenyl group having 2 to 20 carbon atoms), cycloalkyl (e.g., cycloalkyl group having 3 to 10 carbon atoms), aryl (e.g., aryl group having 6 to 20 carbon atoms), heteroaryl (e.g., aryl group having 3 to 10 carbon atoms), alkoxy (e.g., alkoxy group having 1 to 20 carbon atoms), acyl and halogen-containing functional groups. The substituents may be the same or different.

As known to those skilled in the art, the “acyl” may be an R—C(═O)—* (* is a linking symbol, where R is an alkyl group having 1 to 20 carbon atoms, a cycloalkyl group having 3 to 20 carbon atoms, an aryl group having 6 to 20 carbon atoms, or an arylalkyl group having 7 to 20 carbon atoms). The “acyl” is bonded to a ring of cellulose through ester bonds (via oxygen atoms) in cellulose.

For convenience, the “alkyl”, “alkenyl”, “cycloalkyl”, “aryl”, “heteroaryl”, “alkoxy” and “acyl” are each non-halogenated groups that do not include halogens. The composition for a first phase difference layer may include the cellulose ester group alone or a mixture of the above cellulose ester group.

The “halogen” means fluorine (F), Cl, Br or I, and preferably means F.

The “halogen-containing functional group” is an organic functional group containing one or more halogens and may include aromatic, aliphatic or alicyclic functional groups. For example, the halogen-containing functional group may refer to a halogen-substituted alkyl group having 1 to 20 carbon atoms, a halogen-substituted alkenyl group having 2 to 20 carbon atoms, a halogen-substituted alkynyl group having 2 to 20 carbon atoms, a halogen-substituted cycloalkyl group having 3 to 10 carbon atoms, a halogen-substituted alkoxy group having 1 to 20 carbon atoms, a halogen-substituted acyl group having 6 to 20 carbon atoms, or a halogen-substituted aryl alkyl group having 7 to 20 carbon atoms, but is not limited thereto.

The “halogen-substituted acyl group” may be an R′—C(═O)—* (* is a linkage symbol, where R′ is a halogen-substituted alkyl group having 1 to 20 carbon atoms, a halogen-substituted cycloalkyl group having 3 to 20 carbon atoms, a halogen-substituted aryl group having 6 to 20 carbon atoms, or a halogen-substituted arylalkyl group having 7 to 20 carbon atoms). The “halogen-substituted acyl group” is bonded to a ring of cellulose through ester bonds (via oxygen atoms) in cellulose.

The cellulose ester-based polymer may be prepared by conventional methods known to those skilled in the art or may be used by purchasing commercially available products. For example, a cellulose ester-based polymer having an acyl as a substituent may be prepared by reacting a sugar monomer constituting cellulose of Chemical Formula 1 described above or a polymer of sugar monomers with trifluoroacetic acid or trifluoroacetic anhydride, or by reacting trifluoroacetic acid or trifluoroacetic anhydride followed by further reacting with an acylating agent (e.g., an anhydride of a carboxylic acid, or a carboxylic acid), or by reacting trifluoroacetic acid or trifluoroacetic anhydride with an acylating agent together and then polymerizing.

A polystyrene-based polymer may include a repeating unit of Chemical Formula 2 below:

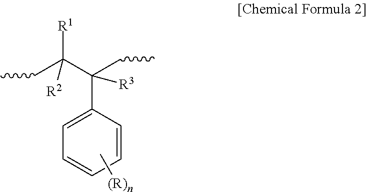

(In Chemical Formula 2 above, [symbol] is a linking site, R¹, R² and R³ are each independently a hydrogen atom, an alkyl group, a substituted alkyl group, or a halogen, R is each independently an alkyl, a substituted alkyl, a halogen, a hydroxy, a carboxyl, a nitro, an alkoxy, an amino, a sulfonate, a phosphate, an acyl, an acyloxy, a phenyl, an alkoxycarbonyl or a cyano group, and n is an integer from 0 to 5).

The polystyrene-based polymer may be a halogen-containing polystyrene-based polymer, containing a halogen. In Chemical Formula 2 above, one or more of R¹, R² and R³ may be a halogen and/or at least one R may be a halogen. In one embodiment, the halogen means fluorine (F), Cl, Br or I, and preferably F.

A halogen-containing polystyrene-based polymer may be formed by polymerizing a mixture including, for example, one or more of 1-(2,2-difluoroethenyl)-2-fluorobenzene and 1′,2′,2′-trifluorostyrene. The mixture may further include styrene.

Preferably, the positive C layer may be a liquid crystal layer. In this case, it is possible to provide a thinning effect of the polarizing plate.

The positive C layer may have a thickness of 10 μm or less, specifically more than 0 μm and 10 μm or less, and specifically 1 μm to 5 μm. Within the above range, it may be used in a polarizing and may provide a thinning effect of the polarizing.

The positive A layer may be a liquid crystal layer or a non-liquid crystal layer.

If the positive A layer is a liquid crystal layer, the positive A layer may be formed by coating a composition for a liquid crystal layer onto a substrate film and the like, and then drying and curing the same. Since the positive A layer in the form of a liquid crystal layer is manufactured without processes such as stretching, it may be easy to reduce the bending of the polarizing plate. The composition for a liquid crystal layer may be formed from a conventional composition for liquid crystal layers known to those skilled in the art. For example, the composition for a liquid crystal layer may be a nematic or discotic liquid crystal.

When the positive A layer is a non-liquid crystal layer, the positive A layer may be a film made of one or more resins selected from: a cellulose-based resin including triacetylcellulose (TAC), a polyester-based resin including polyethylene terephthalate, polybutylene terephthalate, polyethylene naphthalate (PET) and polybutylene naphthalate; a cyclic olefin polymer-based resin, a polycarbonate-based resin, a polyethersulfone-based resin, a polysulfone-based resin, a polyamide-based resin, a polyimide-based resin, a polyolefin-based resin, a polyarylate-based resin, a polyvinyl alcohol-based resin, a polyvinyl chloride-based resin and a polyvinylidene chloride-based resin. Preferably, the positive A layer may be a cyclic olefin polymer-based layer.

Preferably, the positive A layer may be a liquid crystal layer. In this case, it is possible to provide a thinning effect of the polarizing plate.

The positive A layer may have a thickness of 10 μm or less, specifically more than 0 μm and 10 μm or less, and specifically 3 μm to 5 μm. Within the above range, it may be used in a polarizing, and may provide a thinning effect of the polarizing plate.

In one embodiment, the slow axis of the positive A layer may form an angle of 40 to 50°, for example, 45°, with respect to the light absorption axis of the polarizer. Within the above range, the anti-reflection effect of the laminate of the phase difference layer described above may be higher.

Meanwhile, if at least one of the positive A layer and the positive C layer is a liquid crystal layer, it is possible to provide a thinning effect of the polarizing plate. However, the liquid crystal layer may be contaminated by dichroic substances, such as iodine, that may leach from the polarizer when the polarizing plate is left in high temperature and high humidity for a long period of time. However, the polarizer protection layer described above may prevent contamination by dichroic substances, such as iodine, by providing a barrier effect, and may provide a thinning effect of the polarizing plate as an anisotropic optical layer without affecting the optical effects of the positive A layer and the positive C layer.

### Adhesive Layer

The adhesive layer may be formed from a composition including an adhesive resin. In one embodiment, the adhesive resin may include one or more of (meth)acrylic-based resins, epoxy-based resins, silicone-based resins and urethane-based resins, and preferably, a (meth)acrylic resin may be used. In one embodiment, the adhesive layer may be a pressure-sensitive adhesive layer.

The adhesive layer may have a thickness of 3 to 20 μm, for example, 5 to 10 μm. Within the above range, it is possible to provide a thinning effect of the polarizing plate.

### Bonding Layer

The bonding layer may include a bonding layer formed from a bonding composition including a bonding resin.

In one embodiment, the bonding layer may include a bonding layer formed from a photocurable bonding agent or a heat-curable bonding agent. In one embodiment, the photocurable bonding agent may include an epoxy-based resin, a (meth)acrylic resin-based and a photoinitiator. The epoxy-based resin, the (meth)acrylic-based resin and the photoinitiator may each be of a conventional type known to those skilled in the art.

The bonding layer may have a thickness of 0.1 to 5 μm, for example, 0.1 to 3 μm. Within the above range, it is possible to provide a thinning effect of the polarizing plate.

The polarizing plate may further include a protection layer on the other surface of the polarizer.

### Protection Layer

The protection layer may be laminated on an upper surface of the polarizer to increase the mechanical strength of a polarizing plate.

The protection layer may be a coating layer or film of a liquid crystal layer or a non-liquid crystal layer. For example, the protection layer may be an optically transparent film. Specifically, the protection layer may be a film made of one or more resins selected from a cellulose-based resin including triacetylcellulose (TAC), a polyester-based resin including polyethylene terephthalate, polybutylene terephthalate, polyethylene naphthalate, polybutylene naphthalate and the like, a cyclic olefin polymer (COP)-based resin, a polycarbonate-based resin, a polyethersulfone-based resin, a polysulfone-based resin, a polyamide-based resin, a polyimide-based resin, a polyolefin-based resin, a polyarylate-based resin, a polyvinyl alcohol-based resin, a polyvinyl chloride-based resin and a polyvinylidene chloride-based resin. In one embodiment, the protection layer may be a cellulose-based or cyclic olefin polymer (COP)-based protection layer including triacetylcellulose (TAC) and the like.

The protection layer may have a thickness of 25 μm to 80 μm, for example, 30 μm to 60 μm. Within the above range, it may be used in a polarizing plate.

The protection layer may be laminated to a polarizer by a bonding layer or an adhesive layer. The bonding layer or the adhesive layer may be formed from a thermosetting or photocurable bonding composition. The bonding layer or the adhesive layer may have a thickness of 1 μm to 30 μm, for example, 2 μm to 10 μm, or 2 μm to 3 μm.

A functional coating layer may be additionally formed on at least one surface of the protection layer. The functional coating layer may be a hard coating layer, an anti-fingerprint layer, an anti-reflective layer, a low-reflection layer, an anti-glare layer, a primer layer and the like.

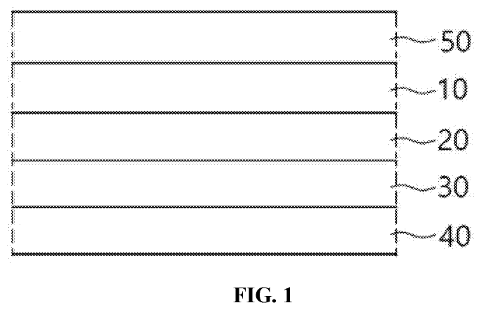

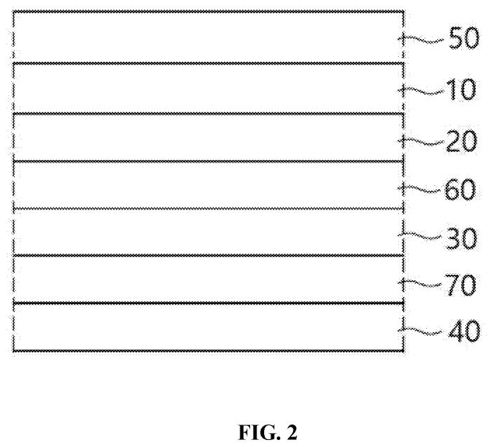

FIGS. 1 and 2 are cross-sectional diagrams of a polarizing plate according to an embodiment of the present invention.

Referring to FIG. 1, the polarizing plate may include a polarizer 10; a polarizer protection layer 20, a positive A layer 30 and a positive C layer 40 sequentially laminated on a lower surface of a polarizer 10; and a protection layer 50 laminated on an upper surface of the polarizer 10.

Referring to FIG. 2, the polarizing plate may include a polarizer 10; a polarizer protection layer 20, a first adhesive layer or bonding layer 60, a positive A layer 30, a second adhesive layer or bonding layer 70 and a positive C layer 40 sequentially laminated on a lower surface of the polarizer 10; and a protection layer 50 laminated on an upper surface of the polarizer 10.

An optical display apparatus of the present invention includes the polarizing plate of the present invention. In one embodiment, the optical display apparatus may be a liquid crystal display device or a light-emitting diode display device.

A liquid crystal display device includes a liquid crystal panel, the polarizing plate of the present invention laminated on a light-emitting surface of the liquid crystal panel and a polarizing plate (light source-side polarizing plate) disposed on a light-incident surface of the liquid crystal panel. The polarizing plate disposed on the light-incident surface may include a polarizing plate commonly known to those skilled in the art. The polarizing plate of the present invention may be used as a viewing-side polarizing plate. However, the present invention is not limited thereto, and the polarizing plate of the present invention may be applied as a viewing-side polarizing plate or a light source-side polarizing plate.

A light-emitting diode display device includes a panel including light-emitting diodes and the polarizing plate of the present invention positioned on the panel. The light-emitting diode display device may be an organic light-emitting diode display device, an inorganic light-emitting diode display device, or an organic-inorganic light-emitting diode display device.

Hereafter, the constitutions and operation of the present invention will be described in more detail through preferred embodiments of the present invention. However, the following embodiments are intended to aid in understanding the present invention, and the scope of the present invention is not limited to the following embodiments.

### Example 1

### (1) Production of Polarizer

A polyvinyl alcohol-based film (TS3000, KURARAY, thickness: 30 μm) washed with water at 25° C. was subjected to swelling treatment in a swelling bath of water at 25° C. The film that passed through the swelling bath was treated for 65 seconds in a dyeing bath at 30° C. containing an aqueous solution including 1 mol/mL of potassium iodide and 0.45 wt % of boric acid. The film that passed through the dyeing bath was stretched at an MD uniaxial stretching ratio of 5.6 times in a wet stretching bath containing an aqueous solution at 60° C. containing 3.6 wt % of boric acid. The film that passed through the wet stretching bath was treated for 65 seconds in a crosslinking bath containing an aqueous solution at 25° C. containing 3 wt % of boric acid. The film that passed through the crosslinking bath was treated for 10 seconds in a color-correcting bath including a color-correcting solution, which is a 23° C. aqueous solution containing 2.5 wt % potassium iodide. The film that passed through the color-correcting bath was washed with water and dried to produce a polarizer (thickness: 10 μm).

### (2) Manufacture of Polarizing Plate

A liquid crystal layer (in-plane phase difference of 142 nm at wavelength 550 nm, thickness: 2 μm, MR4DN-I (0.83), DNP) was used as a positive A layer.

A liquid crystal layer (thickness direction phase difference of −80 nm at wavelength 550 nm, thickness: 1 μm, MCP-I (80), DNP) was used as a positive C layer.

A non-stretched polyethylene terephthalate film was 1 manufactured by melt-extruding a composition including polyethylene terephthalate. The manufactured non-stretched polyethylene terephthalate film was then uniaxially stretched in the mechanical direction at a stretching ratio of 4 times and heat-set to manufacture a polarizer protection layer. The polarizer protection layer was a polyethylene terephthalate film and an anisotropic optical layer. At a wavelength of 550 nm, the in-plane phase difference was 1,000 nm, the degree of biaxiality was 1, and the thickness was 5 μm.

A photocurable bonding agent (epoxy resin bonding agent) was applied to an upper surface of the manufactured polarizer, and a triacetylcellulose film was laminated as a protection layer.

The manufactured polyethylene terephthalate film, the positive A layer and the positive C layer were sequentially positioned on a lower surface of the manufactured polarizer and bonded by using a photocurable bonding agent to manufacture a polarizing plate. In this case, a slow axis of the positive A layer formed a 45° angle with respect to the light absorption axis of the polarizer, and a slow axis of the polyethylene terephthalate film was parallel to a light absorption axis of the polarizer.

### Example 2

A polarizing plate was manufactured in the same manner as in Example 1, except that the polyethylene terephthalate film in Example 1 was stretched in the mechanical direction, and the stretching ratio and stretching temperature were changed.

### Example 3

A polarizing plate was manufactured in the same manner as in Example 1, except that the polyethylene terephthalate film in Example 1 was stretched in the mechanical direction, and the stretching ratio and stretching temperature were changed.

### Comparative Example 1

A polarizing plate was manufactured in the same manner as in Example 1, except that the polyethylene terephthalate film in Example 1 was stretched in the mechanical direction, and the stretching ratio and stretching temperature were changed.

### Comparative Example 2

A polarizing plate was manufactured in the same manner as in Example 1, except that the polyethylene terephthalate film in Example 1 was stretched in the transverse direction, and the stretching ratio and stretching temperature were changed.

### Comparative Example 3

A polarizing plate was manufactured using the same manner as in Example 1, except that the polyethylene terephthalate film in Example 1 was attached at a 90° angle when bonded to the polarizer.

### Comparative Example 4

A polarizing plate was manufactured in the same manner as in Example 1, except that the polyethylene terephthalate film in Example 1 was replaced with an isotropic triacetylcellulose (TAC) film.

The physical properties shown in Table 1 below were evaluated by using the polarizing plates of the examples and comparative examples.

(1) Anti-reflection effect: The maximum omnidirectional reflectance and color change were calculated by using the Mirror Extension method with the Techwiz 1D simulation program, and the OLED panel was based on a perfect reflector.

(2) Visual evaluation of iodine leaching panel corrosion: A polarizing film was laminated onto aluminum foil and placed in a constant temperature and humidity chamber at 85° C. In this case, the liquid crystal and the polarizing film were manufactured using UV bonding, and the surface laminated to the aluminum was manufactured using PSA bonding. An evaluation laminated film (thickness: 1T) was positioned between the upper and lower glass to suppress corrosion occurring only in specific locations and to ensure that the constant temperature and humidity conditions were evenly applied to the entire surface. After 288 hours, the degree of corrosion was judged as good or poor by visual evaluation. The criteria were judged as poor if corrosion was confirmed with the eye, and good if it was judged as normal without any change.

TABLE 1

| | | Example | | | Comparative Example | | | |
|---|---|---|---|---|---|---|---|---|
| | | 1 | 2 | 3 | 1 | 2 | 3 | 4 |
| Polarizer | Re (nm) | 1000 | 1000 | 100 | 1000 | 1000 | 1000 | 0 |
| protection | NZ | 1 | 1.2 | 1 | 0.9 | 1.3 | 1 | — |
| layer | Angle (°) | 0 | 0 | 0 | 0 | 0 | 90 | — |
| | Thickness | 5 | 5 | 1 | 5 | 5 | 5 | 40 |
| | (μm) | | | | | | | |

| | | | | | | | |
|---|---|---|---|---|---|---|---|
| Maximum | 4.3 | 4.5 | 4.0 | 4.0 | 5.1 | 9.7 | 4.3 |
| omnidirectional | | | | | | | |
| reflectance (%) | | | | | | | |
| Color change | 284 | 224 | 228 | 1024 | 254 | 1213 | 220 |
| Visual evaluation of | Good | Good | Good | Good | Good | Good | Good |
| iodine leaching panel | | | | | | | |
| corrosion | | | | | | | |

*Angle: The angle formed by the slow axis of the polarizer's protection layer with respect to the light absorption axis of the polarizer.
*Color change: The value obtained by multiplying the entire range of a* and the entire range of b* based on the La*b* color coordinate system.

As shown in Table 1 above, the polarizing plate of the present invention provided a maximum omnidirectional reflectance of 4.5% or less, a color change value of 1,000 or less, and a good effect in panel corrosion evaluation. In addition, the polarizing plate of the present invention provided a thinning effect by including an anisotropic optical layer.

On the other hand, as shown in Table 1 above, the comparative examples that did not satisfy the degree of biaxiality of the polarizer protection layer or did not satisfy the angle between the light absorption axis of the polarizer and the slow axis of the polarizer's protection layer showed poor effects compared to the example in terms of color change and maximum omnidirectional reflectance. In addition, Comparative Example 4, which had an isotropic optical layer, failed to provide a thinning effect compared to the examples, because the thickness of the isotropic optical layer was too thick.

Simple variations or modifications of the present invention can be easily practiced by those skilled in the art, and all of such variations or modifications are considered to be included within the scope of the present invention.

1. A polarizing plate, comprising:
a polarizer; a polarizer protection layer sequentially laminated from the polarizer on one surface of the polarizer; and a laminate of a positive A layer and a positive C layer,
wherein the polarizer protection layer is an anisotropic optical layer,
wherein the polarizer protection layer has an in-plane phase difference (Re) of 10 nm or more and a degree of biaxiality (NZ) of more than 0.9 and 1.2 or less at a wavelength of 550 nm, and
wherein a slow axis of the polarizer protection layer is parallel to a light absorption axis of the polarizer.

2. The polarizing plate of claim 1, wherein the polarizer protection layer has an in-phase phase difference of 10 to 1,000 nm at a wavelength of 550 nm.

3. The polarizing plate of claim 1, wherein a slow axis of the polarizer protection layer is parallel to a mechanical direction of the polarizer protection layer.

4. The polarizing plate of claim 1, wherein the polarizer protection layer is a polyester-based, polymethyl methacrylate-based or cyclic olefin polymer-based film.

5. The polarizing plate of claim 1, wherein the polarizer protection layer has a thickness of 20 μm or less.

6. The polarizing plate of claim 1, wherein the positive A layer is a liquid crystal layer, and the positive C layer is a liquid crystal layer.

7. The polarizing plate of claim 1, wherein the polarizer protection layer, the positive A layer and the positive C layer are sequentially laminated from the polarizer.

8. The polarizing plate of claim 1, wherein the positive C layer has a thickness direction phase difference of −150 nm to −50 nm at a wavelength of 550 nm.

9. The polarizing plate of claim 1, wherein the positive A layer has an in-plane phase difference of 100 nm to 160 nm at a wavelength of 550 nm.

10. An optical display apparatus, comprising the polarizing plate according to claim 1.
